(19) United States
(12) Patent Application Publication
(10) Pub. No.: US 2024/0006371 A1
(43) Pub. Date: Jan. 4, 2024

(54) SEMICONDUCTOR DEVICE INTERCONNECT STRUCTURE

(71) Applicant: INTERNATIONAL BUSINESS MACHINES CORPORATION, ARMONK, NY (US)

(72) Inventors: Keiji Matsumoto, Yokohama-shi (JP); Toyohiro Aoki, Yokohama (JP); Takahito Watanabe, Yokohama (JP); RISA MIYAZAWA, Isehara (JP); Takashi Hisada, Hachiouji-shi (JP)

(21) Appl. No.: 17/809,574

(22) Filed: Jun. 29, 2022

(51) Int. Cl. H01L 23/00

(52) U.S. Cl. CPC H01L 24/81; H01L 24/11; H01L 24/16; H01L 24/29; H01L 2224/11849; H01L 2224/1148; H01L 2224/16237; H01L 2224/2902; H01L 2224/0401; H01L 2224/73204; H01L 2224/81815

(57) ABSTRACT

An interconnect system may connect a first semiconductor device with second semiconductor device. The interconnect system includes patterned mask, conductive pads, solder bumps, and an adhesion layer. The patterned mask may be retained after it is utilized to fabricate the conductive pads and the solder bumps. The patterned mask may be thinned, and the adhesion layer may be formed upon the thinned patterned mask and upon the solder bumps. The adhesion layer and the solder bumps may be partially removed or planarized and the top surface of the adhesion layer that remains between the solder bumps may be coplanar with the top surface of the solder bumps.

### BACKGROUND

The present disclosure relates generally to the field of semiconductor device technology and more particularly to an interconnect structure that may connect the semiconductor device to an external device, such as a second semiconductor device, a carrier, or the like.

### SUMMARY

In an embodiment of the present disclosure, a semiconductor system fabrication method is presented. The method includes forming a patterned mask upon a first integrated circuit (IC) package. The patterned mask includes a trench that exposes at least a portion of a wiring contact and a portion of an external surface of the first IC package. The method further includes forming a contact pad within the trench upon the exposed portion of the wiring contact and upon the exposed portion of the external surface of the first IC package. The method further includes forming a solder bump within the trench upon the contact pad. The method further includes, subsequent to forming the solder bump, thinning the patterned mask. The method further includes forming an adhesion layer upon the thinned patterned mask. The method further includes planarizing the adhesion layer and the solder bump; and joining the first IC package with a second IC package by connecting the contact pad of the first IC package with a contact pad of the second IC package with the solder bump and by connecting the thinned patterned mask of the first IC package with a dielectric layer of the second IC package with the adhesion layer.

In another embodiment of the present disclosure, another semiconductor device fabrication method is presented. The method includes forming a patterned mask upon a first integrated circuit (IC) package. The patterned mask includes a trench that exposes at least a portion of a wiring contact and a portion of an external surface of the first IC package. The method further includes forming a contact pad within the trench upon the exposed portion of the wiring contact and upon the exposed portion of the external surface of the first IC package. The method further includes forming a solder bump within the trench upon the contact pad. The method further includes, subsequent to forming the solder bump, thinning the patterned mask. The method further includes forming an adhesion layer upon the thinned patterned mask. The method further includes planarizing the adhesion layer and the solder bump.

In another embodiment of the present disclosure, another semiconductor system fabrication method is presented. The method includes forming a patterned mask upon a first integrated circuit (IC) package. The patterned mask includes a trench that exposes at least a portion of a wiring contact and a portion of an external surface of the first IC package. The method further includes forming a contact pad within the trench upon the exposed portion of the wiring contact and upon the exposed portion of the external surface of the first IC package. The method further includes forming a solder bump within the trench upon the contact pad. The method further includes forming an adhesion layer upon the thinned patterned mask. The method further includes planarizing the adhesion layer and the solder bump. The method further includes joining the first IC package with a second IC package by connecting the contact pad of the first IC package with a contact pad of the second IC package with the solder bump and by connecting the patterned mask of the first IC package with a dielectric layer of the second IC package with the adhesion layer.

The above and other aspects, features, and advantages of various embodiments of the present disclosure will be more apparent from the following description taken in conjunction with the accompanying drawings.

### BRIEF DESCRIPTION OF THE DRAWINGS

The above and other aspects, features, and advantages of various embodiments of the present disclosure will be more apparent from the following description taken in conjunction with the accompanying drawings.

FIG. 1 depicts an exploded cross-sectional view of a semiconductor device system, in accordance with an embodiment of the present disclosure.

FIG. 2 though FIG. 6 are cross-sectional fabrication views of a semiconductor device that includes an interconnect system, in accordance with embodiments of the present disclosure.

FIG. 7 depicts a fabrication method of fabricating a semiconductor device that includes an interconnect system, in accordance with embodiments of the present disclosure.

FIG. 8 depicts an cross-sectional view of a semiconductor device system, in accordance with an embodiment of the present disclosure.

FIG. 9 depicts cross-sectional view a semiconductor device, in accordance with embodiments of the present disclosure.

### DETAILED DESCRIPTION

Embodiments of the present disclosure recognize that in modern electronic systems, a first semiconductor device, such as an integrated circuit (IC) chip, processor, or the like, may be connected electrically and mechanically to a second semiconductor device, such as an IC chip carrier, interposer, a second IC chip, processor, or the like. In a particular known interconnect topology, conductive pads of the first semiconductor device may be connected to conductive pads of the second semiconductor device by a respective solder bump. These solder bumps typically protrude from an associated perimeter connection surface. A non-conductive paste may also be utilized to mechanically bond or connect the first semiconductor device with the second semiconductor device. Typically, the non-conductive paste is formed over both the perimeter connection surface and the solder bumps and may ultimately increase electrical resistance and joint reliability issues between the pads through the solder bump.

Embodiments of the present disclosure recognize that as the pitch between solder bumps decreases, the height at which the solder bumps protrude from the perimeter connection surface typically also decreases, which causes difficulties in electrically and mechanically bonding the respective pads with the solder bumps and increases the propensity of electrical shorting between neighboring solder bumps.

Embodiments of the present disclosure provide an interconnect system that connects the first semiconductor device with the second semiconductor device. The interconnect system may include a mask, conductive pads, solder bumps, and an adhesion layer. The mask may be retained after it is utilized to fabricate the conductive pads and the solder bumps. The mask may be thinned, and the adhesion layer may be formed upon the thinned mask and upon the solder bumps. The adhesion layer and the solder bumps may be partially removed or planarized, so that the top surface of the adhesion layer that remains between the solder bumps may be coplanar or substantially coplanar with the top surface of the solder bumps.

Embodiments of the present disclosure provide for solder bump surface area to achieve adequate connection of the respective pads. Further, due to the adhesion layer that remains between the solder bumps, adequate bonding between the first semiconductor device and the second semiconductor device may be achieved without non-conductive paste. Therefore, the potential electrical resistance increase and joint reliability issues between the pads through the solder bump in the known interconnect topology caused by the non-conductive paste are reduced and/or eliminated. Further, the interconnect system of the embodiments may reduce the propensity of electrical shorting between neighboring solder bumps due to the planar adhesion layer and solder bumps.

Embodiments of the present disclosure provide a method of forming a semiconductor device that includes the interconnect system. The method may include applying a mask to the semiconductor device. The method may include patterning the mask to form a trench. The method may further include forming a pad upon the semiconductor device within the trench and forming a solder bump upon the pad within the trench. The method may further include thinning the mask and thereby at least partially exposing the solder bump. The method may further include forming an adhesion layer upon the thinned mask and upon the exposed solder bump. The method may further include planarizing the top surface of the adhesion layer and the top surface of the solder bump.

Referring now to the FIGS., wherein like components are labeled with like numerals, exemplary embodiments that involve a semiconductor carrier, semiconductor device, such as a wafer, chip, integrated circuit, microdevice, etc. in accordance with embodiments of the present disclosure are shown and will now be described in greater detail below. It should be noted that while this description may refer to components in the singular tense, more than one component may be depicted throughout the FIGS. The specific number of components depicted in the FIGS. and the orientation of the structural FIGS. was chosen to best illustrate the various embodiments described herein.

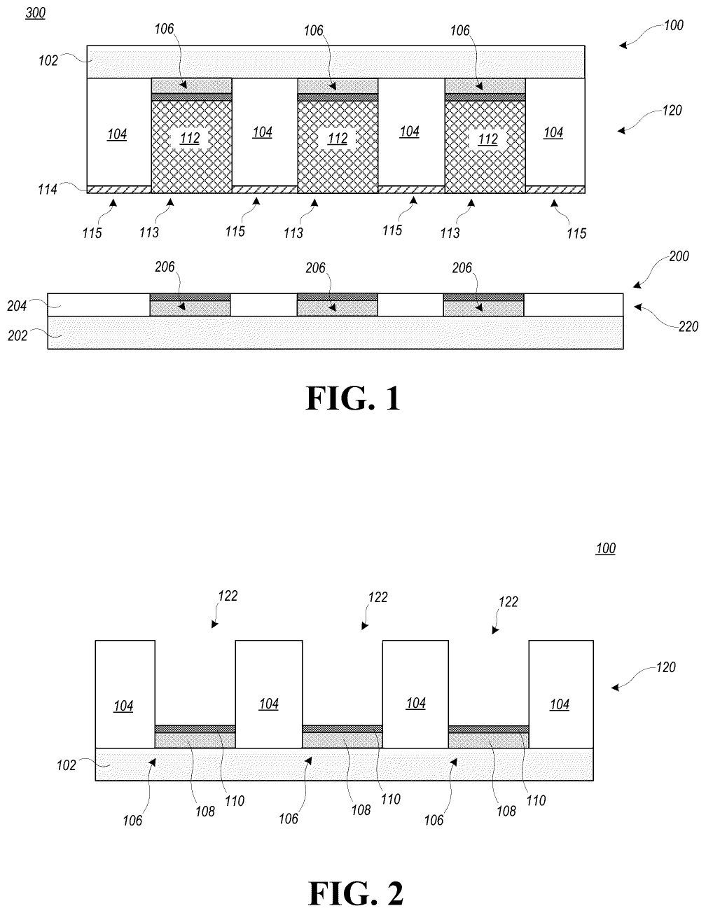

FIG. 1 is an exploded cross-sectional view of a semiconductor device system 300, in accordance with an embodiment of the present disclosure. Semiconductor device system 300 includes semiconductor device 100 and semiconductor device 200. One or both semiconductor devices 100, 200 may include interconnect system 120, according to the embodiments of the present disclosure. For example, and as depicted, semiconductor device 100 includes integrated circuit (IC) package 102 and interconnect system 120 and semiconductor device 200 includes IC package 202 and interconnect system 220.

Interconnect system 120 may include mask 104, conductive pads 106, solder bumps 112, and adhesion layer 114. A solder bump 112 may be upon pad 106. In this manner, the solder bump 112 and pad 106 may form a stack. A mask 104 portion may be adjacent and may contact the sidewall(s) of the pad 106 and solder bump 112 stack. An adhesion layer 114 portion may be upon the mask 104 portion and may also be adjacent and may contact the sidewall(s) of solder bump 112 of the stack. The top surface of the adhesion layer 114 portion may be coplanar with the top surface of the solder bump 112.

In accordance with the embodiments, due to the retention of patterned mask 104, patterned mask 104 exists prior to and after fabrication of the pad 106 and solder bump 112 stack. As such, the patterned mask 104 may deter undercut or void formation within and around the pad 106 and solder bump 112 stack. For example, if patterned mask 104 was not retained after stack formation, the stack would be exposed to etchants or other material removal processes and the propensity of undercut or void formation within and around the pad 106 and solder bump 112 stack would be relatively increased.

Due to the retention of patterned mask 104, (e.g., patterned mask 104 may be a non-strip type resist, permanent resist, or the like) patterned mask 104 may be used as solder bump 112 mask and may also be used as an encapsulation after chip joining. Patterned mask 104 may be especially suitable for fine solder bump 112 pitches, because undercut issues of seed-layer etching during electroplating may be reduced. Additionally, patterned mask 104 may function as a spacer during bonding and it prevents for solder bump 112 to be deformed and short circuits between adjacent interconnects or pads 106, 202 may be reduced.

Interconnect system 220 may include a dielectric layer 204 and conductive pads 206. A dielectric layer 204 portion may be adjacent and may contact the sidewall(s) of the pad 206. The top surface of the dielectric layer 204 may be coplanar with the top surface of the pad 206. Pad 206 may have a same single layer construction, multilayer construction, or the like, relative to pad 106. Alternatively, pad 206 may have a relatively different construction to pad 106. For example, pad 206 may be a single Copper layer while pad 106 may be a Nickel and Silver multi-layer construction.

In embodiments, IC package 102 and/or IC package 202 may be an IC die, such as a processor, field programmable gate array (FPGA), discrete circuit elements, and/or other signal processing devices. The semiconductor device system 300 may be an integration of connected IC package 102 and/or IC package 202 as part of either an intermediate product, such as a motherboard, or a product. The product can be any product that includes semiconductor device system 300, ranging from toys and other low-end applications to advanced computer products having numerous components, such as a display, a keyboard or other input device and/or a central processor, as non-limiting examples.

Interconnect system 120 provides for adequate solder bump 112 surface 113 area to electrically and mechanically connect pad 106 with pad 206. Further, adhesion layer 114 connection surface 115 area, located between neighboring solder bumps 112, may further mechanically connect or bond semiconductor device 100 to semiconductor device 200. Further, interconnect system 120 may reduce the propensity of electrical shorting between neighboring solder bumps 112 due to the planar adhesion layer 114 connection surface 115 and solder bump 112 surface 113.

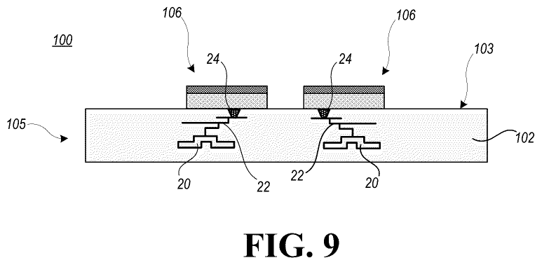

As depicted in FIG. 9, IC package 102 may include one or more semiconductor layers 105, a microdevice 20 formed upon or within the semiconductor layers 105, wiring 22 formed upon or within the semiconductor layers 105, and wiring contact 24 formed upon or within the semiconductor layers 105. A pad 106 may be formed directly upon an external surface 103 of IC package 102 and of wiring contact 24.

The semiconductor layers 105 may include but are not limited to: any semiconducting materials such conventional Si-containing materials, Germanium-containing materials, GaAs, InAs and other like semiconductors. Si-containing materials include, but are not limited to: Si, bulk Si, single crystal Si, polycrystalline Si, SiGe, amorphous Si, silicon-on-insulator substrates (SOI), SiGe-on-insulator (SGOI), annealed poly Si, and poly Si line structures.

Microdevice 20 may be a back end of the line (BEOL) microdevice, front end of the line (FEOL) microdevice, or middle of the line (MOL) microdevice and wiring 22 may be formed below or above one or more wiring layers (e.g., M0-M5, or the like) that may be electrically connected to the microdevice 20. In a particular embodiment, microdevice 20 is a field effect transistor (FET), such as a fin FET, pFET, nFET, nanostructure FET, such as a nanowire FET, nanosheet FET, or the like. In a particular embodiment, wiring 22 may be wiring lines, such as traces, vias, or the like, or may be wide or large area planes such as a source potential, ground potential, power plane, ground plane, VDD plane, VSS, plane, or the like. The wiring 22 may be electrically connected to the contact structure by wiring contact 24. The pad 106, wiring contact 24, and wiring 22 may allow for current to flow from pad 106 through surface 103 of IC package 102 to microdevice 20.

For clarity, IC package 202 may include the one or more semiconductor layers 105, microdevice 20, wiring 22, wiring contact 24, and pad 206 that is directly upon an external surface of IC package 202 and is directly upon an external surface of wiring contact 24. Further, IC packages 102, 202 may include other semiconductor device elements, structures, or features that are known in the art.

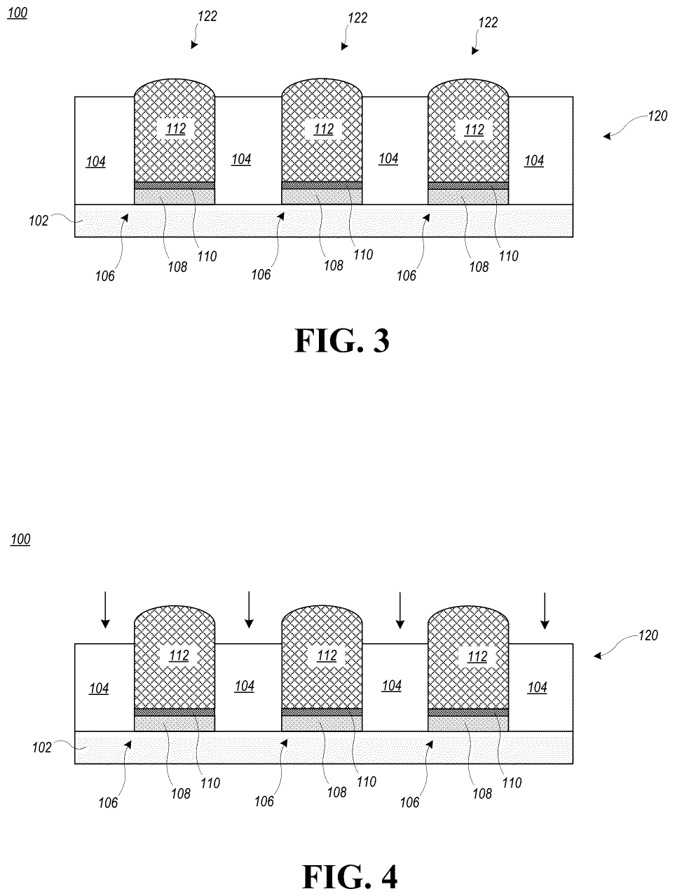

FIGS. 2-6 depict fabrication stages of forming a semiconductor device. Specifically, the method discussed with respect to FIGS. 2-6 relates to forming the semiconductor device 100 and/or semiconductor device 200 to include the interconnect system 120.

For purposes of the description hereinafter, the terms “upper,” “lower,” “right,” “left,” “vertical,” “horizontal,” “top,” “bottom,” and derivatives thereof relate to the described structures and methods, as oriented in the drawing Figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact,” or the like, means that a first element, such as a first structure, and a second element, such as a second structure, are connected without any intermediary conducting, insulating or semiconductor layers at the interface of the two elements. It should be noted that the term “selective to,” such as, for example, “a first element selective to a second element,” means that the first element can be etched, and the second element can act as an etch stop.

The terms “about,” “substantially,” “approximately,” and variations thereof, are intended to include the degree of error associated with measurement of the quantity based upon the equipment available at the time of filing the application. For example, substantial coplanarity between various materials can include an appropriate manufacturing tolerance of ±8%, ±5%, or ±2% difference between the coplanar materials.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. Various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the underlying surface(s). Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes undesired material(s). Examples include etch processes (either wet or dry), and chemical-mechanical planarization (CMP), and the like. Films of both conductors (e.g., polysilicon, aluminum, copper, etc.) and insulators (e.g., various forms of silicon dioxide, silicon nitride, etc.) are used to connect and microdevices 20 and their components. Selective doping of various regions of the semiconductor layers 105 allows the conductivity of the semiconductor layers 105 to be changed with the application of voltage. By creating structures of these various components, millions of microdevices 20 can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a microdevice 20 and the many wires that connect the millions of transistors of a circuit, lithography and etch pattern transfer steps are repeated multiple times. Each pattern being printed on the semiconductor layers 105 is aligned to the previously formed patterns and slowly the conductors, insulators and selectively doped regions are built up to form the final IC package 102. Embodiments of the present disclosure are directed to the semiconductor device 100 interconnect system 120 fabrication stages in which the microdevices 20, wiring 22, wiring contact 24, or the like, have previously been fabricated within the semiconductor layers 105 of IC package 102.

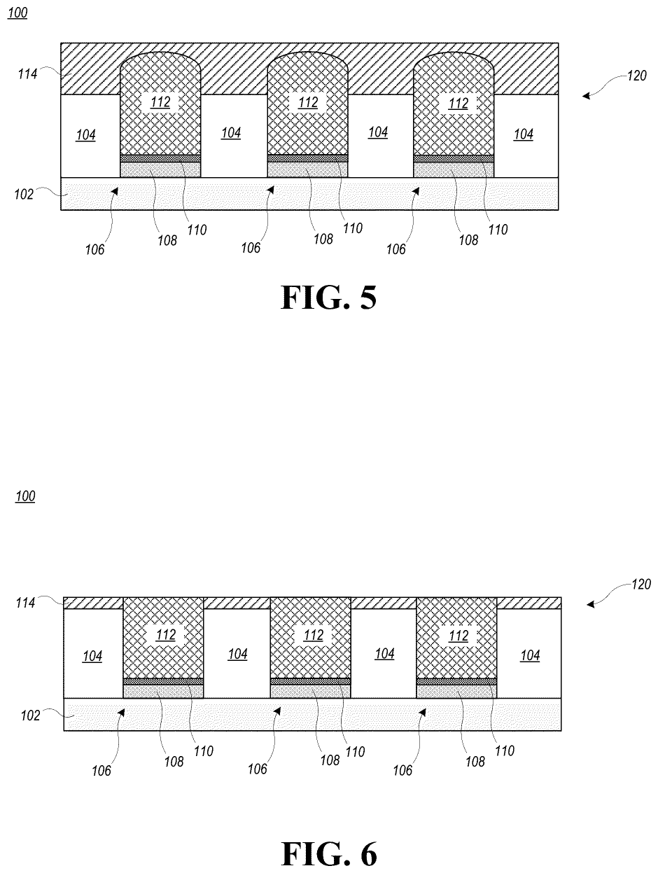

FIG. 2 depicts a cross-sectional view of semiconductor device 100 shown after fabrication operations, in accordance with one or more embodiments. After these fabrication operations, depicted in FIG. 7 as blocks 504, 506, 508, and/or the like, semiconductor device 100 may include IC package 102, a patterned mask 104, trenches 122 within the patterned mask 104, and a pad 106 within each trench 122.

The patterned mask 104 may be formed by initially forming a mask layer, such as a photoresist that may be patterned, upon the external surface 103. The mask layer may be applied as a liquid upon external surface 103 that may dry and be patterned generally forming trenches 122 within the mask layer. Upon patterning of the mask layer to form trenches 122 therein, the retained mask layer may effectively form patterned mask 104. The trenches 122 may expose portions of the external surface 103. For example, when the mask layer is a photoresist, a liquid photoresist may be formed by precision spraying, roller coating, dip coating, spin coating, etc. Exemplary liquid photoresists can be either positive tone resists such as TCIR-ZR8800 PB manufactured by Tokyo Ohka Kogyo America, Inc. or negative tone resists such as JSR THB 126N manufactured by JSR Micro, Inc., Poly(methyl methacrylate) (PMMA), Poly(methyl glutarimide) (PMGI), Phenol formaldehyde resin (DNQ/Novolac), etc. The mask layer may also be a semi-solid film coated, laminated, or otherwise formed upon external surface 103. For example, mask layer may be a dry photoresist such as Asahi CX8040, Asahi CXA240, Riston photoresists, WBR photoresists, or the like.

Patterned mask 104 may be of sufficient thickness to form desired pads 106 and/or solder bump 112 within the trenches 122 patterned therein. Further, the patterned mask 104 may be retained upon the final semiconductor 100 device. In other words, portions of the mask layer that is utilized to form at least pads 106 and/or solder bump 112 within the trenches 122 patterned therein may be retained or present in the final semiconductor 100 device. As such, the mask layer may be chosen to be of a material and a thickness to satisfy such requirements. For example, the mask layer may have a thickness ranging from about 10 um to about 500 um, although a thickness less than 40 um and greater than 500 um have been contemplated. In one embodiment, the mask layer may be about 150 um to 175 um thick.

A pattern may be formed in the mask layer by removing portions of the mask layer. For example, when the mask layer is a photoresist, portions of the mask layer may be exposed to radiation, such as deep ultraviolet light, or electron beams. Once the patterning of the mask layer is completed, portions of the mask layer may be retained and portions of the mask layer may be etched away by an etchant that removes portions of the mask layer material. The portions of the mask layer that are retained may form patterned mask 104. The portions of mask layer that are etched away may reveal the underlying external surface 103 of IC package 102. In various embodiments, etching away the portions of the mask layer form trenches 122, in which electrically conductive material(s) of pad 106 may be subsequently formed therewithin.

The mask may be, for example, a polyimide film or a thin material that does not react with solder (e.g., non-wetting metals such as molybdenum, stainless steel, aluminum, and the like). The patterned mask 104 may be generally aligned to the IC package 102 so that trenches 122 align with exposed wiring contacts 24. This way, a pad 106 may be formed upon the surface 103 and upon the exposed wiring contact 24. In an embodiment, the pads 106 may be arranged in a grid of rows and columns or the like upon the external surface 103 of IC package 102.

In certain embodiments, pad 106 may be formed by depositing conductive material within the trench 122. For example, a single conductive layer pad 106 may be formed by depositing or otherwise forming conductive material (e.g., a metal such as Copper, Nickel, Tungsten, or the like) upon external surface 103 within each trench 122. In a particular embodiment, the conductive material may be formed by plating processes.

In this implementation, IC package 102 may be placed in a plating tool reservoir which contains a plating solution (e.g., plating bath, etc.). The IC package 102 may be attached to a plating tool fixture that accepts IC package 102. An electrical circuit may be created when a negative terminal of a power supply of the plating tool contacts IC package 102 to form a cathode and a positive terminal of the power supply is connected to a plating material in the plating tool to form an anode.

Typically, plating tools or the power supplies themselves have the capability of controlling pulse plating parameters. For example, in a pulse plate operation, the plating tool may control the amount of time the current is off and the amount of time the current is on which may be set upon the plating tool via a user interface. The pulse plating operation may be controlled to a constant current or a constant potential pulse. In the constant current mode, the tops of the current wave form are kept flat by allowing the potential to vary during the pulse on-time. In the constant potential mode, the tops of the potential pulses are kept flat by varying the current during the pulse on-time. Generally, pulse plating is utilized to produce fine grain flat plated material.

The plating material may be a stabilized metal in the plating solution. During the plating process, when an electrical current is passed through the circuit, this metal is dissolved in the plating bath which take-up electrons forming pad 106 upon the exposed IC package 102 within trenches 122. In a particular embodiment, the plating material may be, for example, Copper, Nickel, Tungsten, or the like, and may form the single layer pad 106.

In certain embodiments, pad 106 may be formed by depositing multiple layers of conductive material within the trench 122. For example, as depicted, pad 106 may have a first layer 108 and second layer 110. The first layer 108 may be formed by depositing or otherwise forming conductive material upon external surface 103 within each trench 122. In a particular embodiment, the first layer 108 may be formed by a first plating processes, described above, and the second layer 110 may be formed by a second or subsequent processes. In a particular embodiment, pad 106 may include first layer 108, formed of Nickel, and may include second layer 110, formed of Silver (Ag).

In this implementation, IC package 102 may be placed in another plating tool reservoir which contains another plating solution. The IC package 102 may be attached to the plating tool fixture that accepts IC package 102. An electrical circuit may be created when a negative terminal of a power supply of the plating tool contacts IC package 102 to form a cathode and a positive terminal of the power supply is connected to a second plating material in the plating tool so as to form an anode. The second plating material may be a stabilized metal in the plating solution. During the plating process, when an electrical current is passed through the circuit, this metal is dissolved in the plating bath which take-up electrons forming the second layer 110 of pad 106 upon the exposed first layer 108 within trenches 122. In a particular embodiment, the second plating material may be, for example, Silver, Gold, Tungsten, or the like, and may form the second layer 110 of pad 106.

FIG. 3 depicts a cross-sectional view of semiconductor device 100 shown after fabrication operations, in accordance with one or more embodiments. After these fabrication operations, depicted in FIG. 7 as blocks 510, semiconductor device 100 may include solder bump 112 upon pad 106 within trench 122.

In certain embodiments, solder bump 112 may be formed by depositing solder material upon pad 106 within trench 122. For example, solder bump 112 may be formed by depositing or otherwise forming flowable and/or reflowable solder material upon pad 106 within each trench 122. In a particular embodiment, the conductive material may be formed by plating processes.

In this implementation, IC package 102 may be placed in a solder plating tool reservoir which contains a solder plating solution. The IC package 102 may again be attached to the associated fixture such that the contacts 106 within trenches 122 are exposed to the solder plating solution. An electrical circuit is created when a negative terminal of a power supply contacts IC package 102 to form a cathode and a positive terminal of the power supply is connected to a solder plating material in the solder plating solution to form an anode.

The solder plating material may be a stabilized solder specie in the solder plating solution. During the plating process, when an electrical current is passed through the circuit, this solder specie is dissolved in the solution which take-up electrons forming solder bump 112 upon the pad 106 within trench 122. In a particular embodiment, the solder plating material may be, for example, Tin (Sn). In an exemplary Sn plating process, in a methanesulfonate solution, Sn is oxidized at the anode to Sn²+ by losing two electrons. The Sn²+ associates with two CH₃SO₃ in the solution to form tin methylsulfonate. At the cathode, the Sn²+ is reduced to metallic Sn by gaining two electrons.

In another embodiment, the solder may be formed by injection molded soler (IMS) processes to inject or form solder bump 112 upon wettable pad 106. Thus, the wettable pads 106 depicted in the Figures represent wettable pads and may encompass solder bump limiting metallurgy, such that solder bump 112 is formed upon or wetted to only pad 106. For example, solder bump may be formed upon wettable top surface pad 106 and not upon the top surface of patterned mask 104 that is between neighboring pads 106.

In the IMS process, for example, a solder fill head that dispenses molten solder material into the trenches 122 upon wettable pads 106 forms solder bumps 112. It may be advantageous in the formation of solder bumps 112, that the trench 122 is recessed, such that the top surface of pads 106 is recessed below the top surface of the patterned mask 104 by a predetermined distance to form an adequate and predetermined volume of solder bump 112 material. After solder solidification, a reflow process may be conducted such that solder material voids within trench 122 are removed or reduced. Such reflow process may further result with solder bumps 112 becoming substantially hemispherical solder bumps above the top surface of patterned mask 104.

The IMS process allows controlled filling of trenches 122 of patterned mask 104 with molten solder or molten solder alloys of any composition. It may be accomplished by using an IMS head where the solder is loaded and melted first and then placed tightly against a mold surface and glided across the surface. A vacuum may be provided such that the trenches 122 are under vacuum. Molten solder then flows into the trenches 122 that are under vacuum, thereby filling trenches 122.

Most solder metals are alloys, or combinations of pure elements or materials. Alloys have very different melting characteristics compared to their pure metal forms. Most alloys do not have a single melting temperature or melting point; instead they have a melting range. The upper and lower limits of this range are called the liquidus and solidus temperatures, respectively. The solder begins to melt at its solidus temperature and continues to melt until it reaches the liquidus temperature, where it is completely molten. The difference between the solidus and liquidus temperatures is referred to as the gap. Some solder alloys have a large gap, whereas others have a small or virtually non-existent gap. Therefore, the interconnect system 120 can accomplish the desired result with a wide variety of solder alloys.

For the purposes of this disclosure, a non-exhaustive list of exemplary solder alloys is as follows:
SnAgCu (2.0 to 4.0% Ag, 0.2 to 1.0% Cu, balance Sn), hereinafter referred to as SnAgCu;
SnCu (0.2 to 1.0% Cu, balance Sn), hereinafter referred to as SnCu;
SnAg (2.0 to 4.0% Ag, balance Sn), hereinafter referred to as SnAg;
SnAgIn (10 to 20% In, 3% Ag, balance Sn), hereinafter referred to as SnAgIn;
SnBi (^{˜}57% Bi, balance Sn), hereinafter referred to as SnBi;
SnZn (^{˜}9% Zn, balance Sn), hereinafter referred to as SnZn; and
SnIn (^{˜}52% In, balance Sn), hereinafter referred to as SnIn.

In one embodiment, the solder bump 112 is formed of high lead solder, such as Pb/Sn: 90/10, 95/5, or 97/3. In yet another embodiment, the solder bump 112 is formed of a lead-free alloy, such as AuSn: 80/20, SnAgCu, SnCu, SnAg, or the like.

FIG. 4 depicts a cross-sectional view of semiconductor device 100 shown after fabrication operations, in accordance with one or more embodiments. After these fabrication operations, depicted in FIG. 7 as block 512, semiconductor device 100 may include a thinned patterned mask 104.

The thinning of patterned mask 104 may occur because of a partial removal of a top or upper portion of the patterned mask 104 by a suitable removal technique that selectively removes the top or upper portion of the patterned mask 104 and that also enables the retention of the solder bump 112. The selective removal of patterned mask 104 may include etching, such as a wet etch, a dry etch (e.g., a plasma etch), wet blast, laser ablation (e.g., using excimer laser), or the like. In some embodiments, the thinning of patterned mask 104 may partially expose an upper or top portion of the sidewall(s) of solder bump 112.

FIG. 5 depicts a cross-sectional view of semiconductor device 100 shown after fabrication operations, in accordance with one or more embodiments. After these fabrication operations, depicted in FIG. 7 as block 514, semiconductor device 100 may include an adhesion layer 114 formed upon thinned patterned mask 104 and upon and around solder bump 112.

Adhesion layer 114 may be formed by initially forming an adhesion material upon the top surface of thinned patterned mask 104 and upon around the partially exposed solder bump 112. Adhesion layer 114 may be applied as a liquid that subsequently solidifies (e.g., crosslinking of polymer chains, or the like). Adhesion layer 114 may also be a semi-solid film coated, laminated, or otherwise formed. Adhesion layer 114 may be of sufficient thickness such that the top surface of the adhesion layer 114 may be above or cover the top surface of solder bump 112.

Adhesion layer 114 may be formed of a low modulus adhesion material. The low modulus adhesion material that has a low elastic modulus and has adhesion properties. The modulus of the low modulus adhesion material may be in the range of 1 to 50 MegaPascals (MPa) and preferable between 5 to 10 MPa. The low modulus adhesion material may be at least moderately amenable to being deformed elastically and further moderately absorbs or allows deformation or dimensional changes between semiconductor devices 100, 200, without failing, cracking, peeling, or the like.

The low modulus adhesion material may consist of or otherwise include curable polymers that, after curing, results in hardening of the low modulus adhesion material due to polymer cross-linking. The low modulus adhesion material may be, for example, a weakly cross-linked polymer adhesive compound, elastomeric adhesive, or the like.

In a particular implication, to avoid the risk of short circuit between neighboring solder bumps 112 or pads 106, 206, adhesion layer 114 may be an organic adhesive. Adhesion layer 114 while being compliant may also be adequately non-compliant to resist compression. In other words, adhesion layer 114 may function as a spacer between solder bumps 112.

In a particular implicational, the modulus of cured patterned mask 104 at 250° C. may be 100 MPa and its deformation during bonding (1 MPa) may be only 1% of its the original thickness. Such properties may sufficiently allow patterned mask 104 to function as a solder bump 112 spacer during bonding of semiconductor devices 100, 200. The thickness of patterned mask 104 for 80 μm pitch solder bumps 112 may be 15-30 μm. In this implementation, the modulus of adhesion layer 114 at 250° C. may be above 10 MPa and the deformation during bonding is kept below 0.1% of the original thickness. The adhesion layer 114 thickness for 80 μm pitch solder bumps 112 may be 1-5 μm. Because of this dual layer nature of patterned mask 104 and adhesion layer 114, both bonding (e.g., adequate adhesive requirements) and spacer requirements may be met with reduced propensity for short circuits.

In a particular implementation, after adhesion layer 114 is cured at 200° C., adhesion layer 114 may be tack-less at room temperature, however, adhesion layer 114 is bondable to SiO₂, polyimide (PI), or the like, at a bonding temperature above 200° C. Because adhesion layer 114 may be tack-less at room temperature, CMP or other planarization processes can be performed on adhesion layer 114.

Adhesion layer 114 may have a modulus higher than 5 MPa at 250° C. A modulus higher than 5 MPa at 250° C. may add mechanical integrity (e.g., protection of pads 106, 202, solder bumps 112 from thermo-mechanical stress) in thermal cycling. On the other hand, a modulus of 5 MPa at 250° C. or lower modulus may be preferable to achieve adequate bonding over semiconductor device 100 area due to the compliant property of adhesion layer 114 compensating for slight height difference(s) between adhesion layer 114 and solder bumps 112, and between dielectric 204 and pads 206 of semiconductor device 200.

FIG. 6 depicts a cross-sectional view of semiconductor device 100 shown after fabrication operations, in accordance with one or more embodiments. After these fabrication operations, depicted in FIG. 7 as blocks 516, 518, and 520, semiconductor device 100 may include a planarized adhesion layer 114 such that the top surfaces of thinned adhesion layer 114 and solder bump 112 are coplanar. The planarization of the top surfaces of thinned adhesion layer 114 and solder bump 112 may expose at least the top surface of solder bump 112 while portion(s) of the thinned adhesion layer 114 are retained between and/or adjacent to solder bump 112. The planarization of the top surfaces of thinned adhesion layer 114 and solder bump 112 may be achieved by a CMP or other material removal technique.

FIG. 7 depicts method 500 of fabricating semiconductor device 100. Method 500 may begin and includes forming the mask layer upon the external surface 103 of IC package 102 (block 504). Method 500 may continue with patterning the mask to form patterned mask 104 with trenches 122 patterned therein (block 506). A trench 122 may correspond with the locations (e.g., grid of columns and rows) of underlying wiring contacts 24 of IC package 102. The trench 122 may expose at least a portion of the external surface of wiring contact 24 and a portion of the external surface 103 of IC package 102 that surrounds the wiring contact 24. The trench 122 may be circular, square, rectangular, or the like, column, pillar, opening, etc.

Method 500 may continue with forming pad 106 upon the exposed external surface of wiring contact 24 and exposed portion of the external surface 103 of IC package 102 that surrounds the wiring contact 24 within trench 122 (block 508). The pad 106 may include a single layer or as depicted, a first layer 108 and a second layer 110. Though pad 106 is shown as a two-layer pad 106, pad 106 may include another number of pad layers.

Method 500 may continue with forming solder bump 112 upon the pad 106 within trench 122 (block 510). In a particular implementation solder bump 112 may be formed as part of IMS processes. Method 500 may continue with thinning or partially removing a top or upper portion of the patterned mask 104 (block 512).

Method 500 may continue with forming adhesion layer upon the thinned patterned mask 104 and upon and around the solder bump 112 (block 514). Finally, method 500 may continue with planarizing the top surface of the solder bump 112 and the adhesion layer 114 (block 516). The planarization of the solder bump 112 and adhesion layer 114 may expose the top or external surface of the solder bump 112 (block 518) which may be coplanar with the top or external surface of the adhesion layer 114 (block 520).

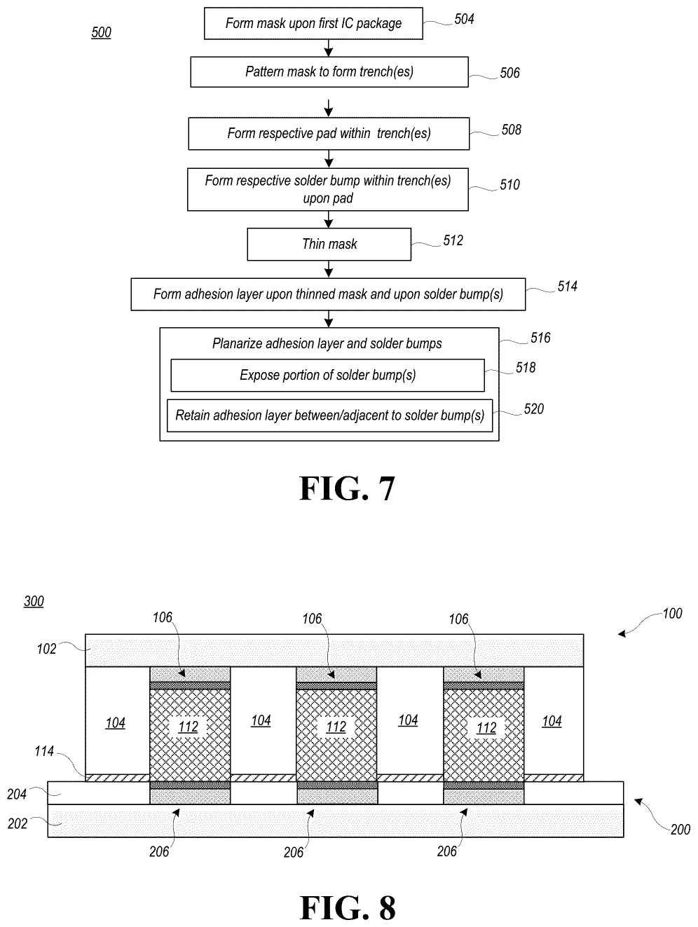

FIG. 8 is a cross-sectional view of semiconductor device system 300, in accordance with an embodiment of the present disclosure. In the depiction, semiconductor device 100 is joined or connected to semiconductor device 200. For example, solder bump 112 is reflowed and mechanically and electrically joins pad 106 with an associated pad 206. In this way, a microdevice 20 within IC package 102 may be electrically connected with a microdevice 20 within IC package 202 (not shown) through an electrical pathway from wiring 22, wiring contact 24, within IC package 102, to wiring 22, wiring contact 24, within IC package 202, by way of pad 106, solder bump 112, and pad 206. Further, patterned mask 104 is mechanically joined or adhered to a respective portion of dielectric layer 204 by adhesion layer 114. The solder bump 112 reflow process may also cure, crosslink, etc. adhesion layer 114 to further or adequately adhere patterned mask 104 to the respective portion of dielectric layer 204.

FIG. 9 is a cross-sectional view of semiconductor device 100 that includes an interconnect system 120, in accordance with embodiments of the present disclosure. IC package 102 may include one or more semiconductor layers 105, microdevice 20 formed upon or within the semiconductor layers 105, wiring 22 formed upon or within the semiconductor layers 105, and wiring contact 24 formed upon or within the semiconductor layers 105. A pad 106 may be formed directly upon an external surface 103 of IC package 102 and of wiring contact 24.

Embodiments of the present disclosure provide interconnect system 120 that connects first semiconductor device 100 with second semiconductor device 200. Interconnect system 120 may include patterned mask 104, conductive pads 106, solder bumps 112, and an adhesion layer 114. The patterned mask 104 may be retained after it is utilized to fabricate the conductive pads 106 and the solder bumps 112. The patterned mask 104 may be thinned, and the adhesion layer 114 may be formed upon the thinned patterned mask 104 and upon the solder bumps 112. The adhesion layer 114 and the solder bumps 112 may be partially removed or planarized. Therefore, the top surface of the adhesion layer 114 that remains between the solder bumps 112 may be coplanar with the top surface of the solder bumps 112.

These embodiments may provide for solder bump 112 surface area to achieve adequate connection of the respective pads 106, 206. Further, due to the adhesion layer 114 that remains between the solder bumps 112, adequate bonding between the first semiconductor device 100 and the second semiconductor device 200 may be achieved without non-conductive paste. Therefore, the potential known electrical resistance increases and joint reliability issues caused by non-conductive paste are reduced and/or eliminated due to no such non-conductive paste being included in interconnect system 120. Further, the interconnect system 120 may reduce the propensity of electrical shorting between neighboring solder bumps 112 due to the planar adhesion layer 114 and solder bumps 112.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor system fabrication method comprising:
forming a patterned mask upon a first integrated circuit (IC) package, the patterned mask comprising a trench that exposes at least a portion of a wiring contact and a portion of an external surface of the first IC package;
forming a contact pad within the trench upon the exposed portion of the wiring contact and upon the exposed portion of the external surface of the first IC package;
forming a solder bump within the trench upon the contact pad;
subsequent to forming the solder bump, thinning the patterned mask;
forming an adhesion layer upon the thinned patterned mask;
planarizing the adhesion layer and the solder bump; and
joining the first IC package with a second IC package by connecting the contact pad of the first IC package with a contact pad of the second IC package with the solder bump and by connecting the thinned patterned mask of the first IC package with a dielectric layer of the second IC package with the adhesion layer.

2. The method of claim 1, wherein thinning the patterned mask comprises:
exposing a top portion of a sidewall of the solder bump.

3. The method of claim 1, wherein the adhesion layer is a low-modulus adhesive layer.

4. The method of claim 1, wherein forming the contact pad within the trench upon the exposed portion of the wiring contact and upon the exposed portion of the external surface of the first IC package comprises:
forming a first metal layer within the trench upon the exposed portion of the wiring contact and upon the exposed portion of the external surface of the first IC package; and
forming a second metal layer within the trench upon the first metal layer.

5. The method of claim 1, wherein forming the patterned mask comprises:
forming a resist layer upon the wiring contact and the external surface of the first IC package; and
forming the trench within the resist layer.

6. The method of claim 1, wherein the wiring contact is electrically connected to a microdevice within the first IC package by wiring.

7. The method of claim 1, wherein connecting the contact pad of the first IC package with the contact pad of the second IC package with the solder bump comprises:
reflowing the solder bump and wetting the solder bump to the contact pad of the first IC package and the contact pad of the second IC package.

8. The method of claim 1, wherein forming the solder bump within the trench upon the injecting molten solder within the trench upon the contact pad.

9. The method of claim 1, wherein the solder bump is a Tin alloy solder bump.

10. A semiconductor device fabrication method comprising:
forming a patterned mask upon a first integrated circuit (IC) package, the patterned mask comprising a trench that exposes at least a portion of a wiring contact and a portion of an external surface of the first IC package;
forming a contact pad within the trench upon the exposed portion of the wiring contact and upon the exposed portion of the external surface of the first IC package;
forming a solder bump within the trench upon the contact pad;
subsequent to forming the solder bump, thinning the patterned mask;
forming an adhesion layer upon the thinned patterned mask; and
planarizing the adhesion layer and the solder bump.

11. The method of claim 10, wherein thinning the patterned mask comprises:
exposing a top portion of a sidewall of the solder bump.

12. The method of claim 10, wherein the adhesion layer is a low-modulus adhesive layer.

13. The method of claim 10, wherein forming the contact pad within the trench upon the exposed portion of the wiring contact and upon the exposed portion of the external surface of the first IC package comprises:
forming a first metal layer within the trench upon the exposed portion of the wiring contact and upon the exposed portion of the external surface of the first IC package; and
forming a second metal layer within the trench upon the first metal layer.

14. The method of claim 10, wherein forming the patterned mask comprises:
forming a resist layer upon the wiring contact and the external surface of the first IC package; and
forming the trench within the resist layer.

15. The method of claim 10, wherein the wiring contact is electrically connected to a microdevice within the first IC package by wiring.

16. The method of claim 10, wherein connecting the contact pad of the first IC package with the contact pad of the second IC package with the solder bump comprises:
reflowing the solder bump and wetting the solder bump to the contact pad of the first IC package and the contact pad of the second IC package.

17. The method of claim 10, wherein forming the solder bump within the trench upon the contact pad comprises:
injecting molten solder within the trench upon the contact pad.

18. The method of claim 10, wherein the solder bump is a Tin alloy solder bump.

19. A semiconductor system fabrication method comprising:
forming a patterned mask upon a first integrated circuit (IC) package, the patterned mask comprising a trench that exposes at least a portion of a wiring contact and a portion of an external surface of the first IC package;
forming a contact pad within the trench upon the exposed portion of the wiring contact and upon the exposed portion of the external surface of the first IC package;
forming a solder bump within the trench upon the contact pad;
forming an adhesion layer upon the thinned patterned mask;
planarizing the adhesion layer and the solder bump; and
joining the first IC package with a second IC package by connecting the contact pad of the first IC package with a contact pad of the second IC package with the solder bump and by connecting the patterned mask of the first IC package with a dielectric layer of the second IC package with the adhesion layer.

20. The method of claim 19, wherein the adhesion layer is a low-modulus adhesive layer.
